(19) United States
(12) Patent Application Publication
(10) Pub. No.: US 2007/0164424 A1
(43) Pub. Date: Jul. 19, 2007

(54) Thermal interconnect and interface systems, methods of production and uses thereof

(76) Inventors: Nancy Dean, Liberty Lake, WA (US); Richard Townsend, Post Falls, ID (US); Paula M. Knoll, San Diego, CA (US); Colin Edie, Spokane, WA (US); My N. Nguyen, Poway, CA (US); Dan Curran, Mountain View, CA (US); Ignatius Joseph Rasiah, Singapore (SG)

Correspondence Address: BUCHALTER NEMER, 18400 VON KARMAN AVE., SUITE 800, IRVINE, CA, 92612, US

(21) Appl. No.: 10/551,305

(22) PCT Filed: Mar. 31, 2004
(86) PCT No.: PCT/US04/10094

§ 371 Date: Nov. 14, 2006

Related U.S. Application Data
(60) Provisional application No. 60/459,716, filed on Apr. 2, 2003.

(51) Int. Cl. H01L 23/34

(52) U.S. Cl. 257/707; 257/E23.087

(57) ABSTRACT

Components and materials, including thermal transfer materials, contemplated herein comprise at least one heat spreader component, at least one thermal interface material and in some contemplated embodiments at least one adhesive material. The heat spreader component comprises a top surface, a bottom surface and at least one heat spreader material. The thermal interface material is directly deposited onto at least part of the bottom surface of the heat spreader component. Methods of forming layered thermal interface materials and thermal transfer materials include: a) providing a heat spreader component, wherein the heat spreader component comprises a top surface, a bottom surface and at least one heat spreader material; b) providing at least one thermal interface material, wherein the thermal interface material is directly deposited onto the bottom surface of the heat spreader component; and c) depositing the at least one thermal interface material onto the bottom surface of the heat spreader component. Methods of forming a thermal solution/package and/or IC package includes: a) providing the thermal transfer material described herein; b) providing at least one adhesive component; c) providing at least one surface or substrate; d) coupling the at least one thermal transfer material and/or material with the at least one adhesive component to form an adhesive unit; e) coupling the adhesive unit to the at least one surface or substrate to form a thermal package; f) optionally coupling an additional layer or component to the thermal package.

This application claims priority to U.S. Provisional Application Ser. No. 60/459,716 filed on Apr. 2, 2003, which is commonly-owned and incorporated herein in its entirety.

### FIELD OF THE INVENTION

The field of the invention is thermal interconnect systems, thermal interface systems and interface materials in electronic components, semiconductor components and other related layered materials applications.

### BACKGROUND

Electronic components are used in ever increasing numbers in consumer and commercial electronic products. Examples of some of these consumer and commercial products are televisions, personal computers, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging. Products and components also need to be prepackaged, such that the product and/or component can perform several related or unrelated functions and tasks. Examples of some of these “total solution” components and products comprise layered materials, mother boards, cellular and wireless phones and telecommunications devices and other components and products, such as those found in US Patent and PCT Application Serial Nos.: 60/396,294 filed Jul. 15, 2002, 60/294,433 filed May 30, 2001 and PCT/US02/17331 filed May 30, 2002, which are all commonly owned and incorporated herein in their entirety.

Components, therefore, are being broken down and investigated to determine if there are better building materials and methods that will allow them to be scaled down and/or combined to accommodate the demands for smaller electronic components. In layered components, one goal appears to be decreasing the number of the layers while at the same time increasing the functionality and durability of the remaining layers. This task can be difficult, however, given that several of the layers and components of the layers should generally be present in order to operate the device.

Also, as electronic devices become smaller and operate at higher speeds, energy emitted in the form of heat increases dramatically. A popular practice in the industry is to use thermal grease, or grease-like materials, alone or on a carrier in such devices to transfer the excess heat dissipated across physical interfaces. Most common types of thermal interface materials are thermal greases, phase change materials, and elastomer tapes. Thermal greases or phase change materials have lower thermal resistance than elastomer tape because of the ability to be spread in very thin layers and provide intimate contact between adjacent surfaces. Typical thermal impedance values range between 0.05-1.6° C.-cm²/W. However, a serious drawback of thermal grease is that thermal performance deteriorates significantly after thermal cycling, such as from −65° C. to 150° C., or after power cycling when used in VLSI chips. It has also been found that the performance of these materials deteriorates when large deviations from surface planarity causes gaps to form between the mating surfaces in the electronic devices or when large gaps between mating surfaces are present for other reasons, such as manufacturing tolerances, etc. When the heat transferability of these materials breaks down, the performance of the electronic device in which they are used is adversely affected.

Thus, there is a continuing need to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) develop reliable methods of producing desired thermal interconnect materials, thermal interface materials and layered materials and components/products comprising contemplated thermal interface and layered materials; d) develop materials that possess a high thermal conductivity and a high mechanical compliance; and e) effectively reduce the number of production steps necessary for a package assembly, which in turn results in a lower cost of ownership over other conventional layered materials and processes.

### SUMMARY

Components and materials, including thermal transfer materials, contemplated herein comprise at least one heat spreader component, at least one thermal interface material and in some contemplated embodiments at least one adhesive material. The heat spreader component comprises a top surface, a bottom surface and at least one heat spreader material. The thermal interface material is directly deposited onto at least part of the bottom surface of the heat spreader component.

Methods of forming layered thermal interface materials and thermal transfer materials include: a) providing a heat spreader component, wherein the heat spreader component comprises a top surface, a bottom surface and at least one heat spreader material; b) providing at least one thermal interface material, wherein the thermal interface material is directly deposited onto the bottom surface of the heat spreader component; and c) depositing the at least one thermal interface material onto at least part of the bottom surface of the heat spreader component.

A method for forming the thermal solution/package and/or IC package includes: a) providing the thermal transfer material described herein; b) providing at least one adhesive component; c) providing at least one surface or substrate; d) coupling the at least one thermal transfer material and/or material with the at least one adhesive component to form an adhesive unit; e) coupling the adhesive unit to the at least one surface or substrate to form a thermal package; f) optionally coupling an additional layer or component to the thermal package.

### BRIEF DESCRIPTION OF THE FIGURES

FIG. 1 shows a contemplated thermal transfer component.

FIG. 2 shows an intermediate component in the process to produce a contemplated thermal transfer component.

FIG. 3 shows an intermediate component in the process to produce a contemplated thermal transfer component.

FIG. 4 shows an intermediate component in the process to produce a contemplated thermal transfer component.

FIG. 5 shows results when using a contemplated adhesive with a contemplated thermal transfer component.

FIG. 6 shows results when using a contemplated adhesive with a contemplated thermal transfer component.

FIG. 7 shows a contemplated thermal transfer component.

FIG. 8 shows results when using a contemplated adhesive with a contemplated thermal transfer component.

FIG. 9 shows a contemplated thermal transfer component.

FIG. 10 shows results when using a contemplated adhesive with a contemplated thermal transfer component.

FIG. 11 shows a contemplated thermal transfer component.

FIG. 12 shows a contemplated thermal transfer component.

FIG. 13 shows a contemplated thermal transfer component.

FIG. 14 shows a contemplated thermal transfer component.

FIG. 15 shows a contemplated thermal transfer component.

FIG. 16 shows a contemplated thermal transfer component.

FIG. 17 shows a contemplated thermal transfer component.

FIG. 18 shows a contemplated thermal transfer component.

### DETAILED DESCRIPTION

A suitable interface material or component should conform to the mating surfaces (“wets” the surface), possess a low bulk thermal resistance and possess a low contact resistance. Bulk thermal resistance can be expressed as a function of the material's or component's thickness, thermal conductivity and area. Contact resistance is a measure of how well a material or component is able to make contact with a mating surface, layer or substrate. The thermal resistance of an interface material or component can be shown as follows:
Θinterface=t/kA+2Θ_{contact} Equation 1
where Θ is the thermal resistance,
   t is the material thickness,
   k is the thermal conductivity of the material
   A is the area of the interface

The term “t/kA” represents the thermal resistance of the bulk material and “2Θ_{contact}” represents the thermal contact resistance at the two surfaces. A suitable interface material or component should have a low bulk resistance and a low contact resistance, i.e. at the mating surface.

Many electronic and semiconductor applications require that the interface material or component accommodate deviations from surface flatness resulting from manufacturing and/or warpage of components because of coefficient of thermal expansion (CTE) mismatches.

A material with a low value for k, such as thermal grease, performs well if the interface is thin, i.e. the “t” value is low. If the interface thickness increases by as little as 0.002 inches, the thermal performance can drop dramatically. Also, for such applications, differences in CTE between the mating components causes the gap to expand and contract with each temperature or power cycle. This variation of the interface thickness can cause pumping of fluid interface materials (such as grease) away from the interface.

Interfaces with a larger area are more prone to deviations from surface planarity as manufactured. To optimize thermal performance, the interface material should be able to conform to non-planar surfaces and thereby lower contact resistance.

Optimal interface materials and/or components possess a high thermal conductivity and a high mechanical compliance, e.g. will yield elastically when force is applied. High thermal conductivity reduces the first term of Equation 1 while high mechanical compliance reduces the second term. The layered interface materials and the individual components of the layered interface materials described herein accomplish these goals. When properly produced, the thermal interface component described herein will span the distance between the mating surface of the heat spreader material and the silicon die component thereby allowing a continuous high conductivity path from one surface to the other surface.

As mentioned earlier, several goals of layered interface materials and individual components described herein are to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) develop reliable methods of producing desired thermal interconnect materials, thermal interface materials and layered materials and components/products comprising contemplated thermal interface and layered materials; d) develop materials that possess a high thermal conductivity and a high mechanical compliance; and e) effectively reduce the number of production steps necessary for a package assembly, which in turn results in a lower cost of ownership over other conventional layered materials and processes.

Pre-attached/pre-assembled thermal solutions and/or IC (interconnect) packages are provided herein that comprise one or more components of a suite of thermal interface materials that exhibit low thermal resistance for a wide variety of interface conditions and demands. Thermal interface materials may comprise PCM45, which is a high conductivity phase change material manufactured by Honeywell International Inc., or metal and metal-based base materials also manufactured by Honeywell International Inc., such as solders, connected to Ni, Cu, Al, AlSiC, copper composites, CuW, diamond, graphite, SiC, carbon composites and diamond composites which are classified as heat spreaders or those materials that work to dissipate heat.

The layered interface materials and the individual components of the layered interface materials described herein accomplish these goals. When properly produced, the heat spreader component described herein will span the distance between the mating surfaces of the thermal interface material and the heat spreader component, thereby allowing a continuous high conductivity path from one surface to the other surface.

Components and materials, including thermal transfer materials, contemplated herein comprise at least one heat spreader component, at least one thermal interface material and in some contemplated embodiments at least one adhesive component. The heat spreader component comprises a top surface, a bottom surface and at least one heat spreader material. The thermal interface material is directly deposited onto at least part of the bottom surface of the heat spreader component. The thermal interface material can be tailored so that it has improved adherence to the substrate surface by formation of bonds between the thermal interface material and the substrate or by incorporating an additional adhesive component into or onto the thermal interface material.

In contemplated embodiments, the thermal interface material is directly deposited onto the bottom side of the heat spreader component. In some contemplated embodiments, the solder material is silk screened or dispensed directly onto the heat spreader by methods such as jetting, thermal spray, liquid molding or powder spray. In yet other contemplated embodiments, a film of thermal interface material is deposited and combined with other methods of building adequate thermal interface material thickness, including direct attachment of a preform or silk screening of a thermal interface material paste.

Methods of forming layered thermal interface materials and thermal transfer materials include: a) providing a heat spreader component, wherein the heat spreader component comprises a top surface, a bottom surface and at least one heat spreader material; b) providing at least one thermal interface material, wherein the thermal interface material is directly deposited onto the bottom surface of the heat spreader component; and c) depositing the at least one thermal interface material onto at least part of the bottom surface of the heat spreader component. Once deposited, the thermal interface material layer comprises a portion that is directly coupled to the heat spreader material and a portion that is exposed to the atmosphere, or covered by a protective layer or film that can be removed just prior to installation of the heat spreader component. Additional methods include providing at least one adhesive component and coupling the at least one adhesive component to at least part of the bottom surface of the at least one heat spreader material and/or to or in at least part of the thermal interface material.

Other layered interface materials described herein comprise at least one crosslinkable thermal interface component and at least one heat spreader component coupled to the thermal interface component. A method of forming contemplated layered interface materials comprises: a) providing a crosslinkable thermal interface component; b) providing a heat spreader component; and c) physically coupling the thermal interface component and the heat spreader component. At least one additional layer, including a substrate layer, can be coupled to the layered interface material.

Several methods and many thermal interface materials can be utilized to form these pre-attached/pre-assembled thermal solution components. A method for forming the thermal solution/package and/or IC package comprises a) providing the thermal transfer material described herein; b) providing at least one adhesive component; c) providing at least one surface or substrate; d) coupling the at least one thermal transfer material and/or material with the at least one adhesive component to form an adhesive unit; e) coupling the adhesive unit to the at least one surface or substrate to form a thermal package; f) optionally coupling an additional layer or component to the thermal package.

As described herein, optimal interface materials and/or components possess a high thermal conductivity and a high mechanical compliance, e.g. will yield elastically when force is applied. High thermal conductivity reduces the first term of Equation 1 while high mechanical compliance reduces the second term. The layered interface materials and the individual components of the layered interface materials described herein accomplish these goals. When properly produced, the heat spreader component described herein will span the distance between the mating surfaces of the thermal interface material and the heat spreader component thereby allowing a continuous high conductivity path from one surface to the other surface. Suitable thermal interface components comprise those materials that can conform to the mating surfaces (“wets” the surface), possess a low bulk thermal resistance and possess a low contact resistance.

A contemplated crosslinkable thermal interface component is produced by combining at least one rubber compound, at least one amine resin and at least one thermally conductive filler. This contemplated interface material takes on the form of a liquid or “soft gel”. As used herein, “soft gel” means a colloid in which the disperse phase has combined with the continuous phase to form a viscous “jelly-like” product. The gel state or soft gel state of the thermal interface component is brought about through a crosslinking reaction between the at least one rubber compound composition and the at least one amine resin composition. More specifically, the amine resin is incorporated into the rubber composition to crosslink the primary hydroxyl groups on the rubber compounds, thus forming the soft gel phase. Therefore, it is contemplated that at least some of the rubber compounds will comprise at least one terminal hydroxyl group. As used herein, the phrase “hydroxyl group” means the univalent group —OH occurring in many inorganic and organic compounds that ionize in solution to yield OH radicals. Also, the “hydroxyl group” is the characteristic group of alcohols. As used herein, the phrase “primary hydroxyl groups” means that the hydroxyl groups are in the terminal position on the molecule or compound. Rubber compounds contemplated herein may also comprise additional secondary, tertiary, or otherwise internal hydroxyl groups that could also undergo a crosslinking reaction with the amine resin. This additional crosslinking may be desirable depending on the final gel state needed for the product or component in which the gel is to be incorporated.

One method for forming crosslinkable thermal interface components disclosed herein comprises a) providing at least one saturated rubber compound, b) providing at least one amine resin, c) crosslinking the at least one saturated rubber compound and the at least one amine resin to form a crosslinked rubber-resin mixture, d) adding at least one thermally conductive filler to the crosslinked rubber-resin mixture, and e) adding a wetting agent to the crosslinked rubber-resin mixture. This method can also further comprise adding at least one phase change material to the crosslinked rubber-resin mixture.

It is contemplated that the rubber compounds could be “self-crosslinkable” in that they could crosslink intermolecularly with other rubber compounds or intramolecularly with themselves, depending on the other components of the composition. It is also contemplated that the rubber compounds could be crosslinked by the amine resin compounds and perform some self-crosslinking activity with themselves or other rubber compounds.

In preferred embodiments, the rubber compositions or compounds utilized can be either saturated or unsaturated. Saturated rubber compounds are preferred in this application because they are less sensitive to thermal oxidation degradation. Examples of saturated rubbers that may be used are ethylene-propylene rubbers (EPR, EPDM), polyethylene/butylene, polyethylene-butylene-styrene, polyethylene-propylene-styrene, hydrogenated polyalkyldiene “mono-ols” (such as hydrogenated polybutadiene mono-ol, hydrogenated polypropadiene mono-ol, hydrogenated polypentadiene mono-ol), hydrogenated polyalkyldiene “diols” (such as hydrogenated polybutadiene diol, hydrogenated polypropadiene diol, hydrogenated polypentadiene diol) and hydrogenated polyisoprene. However, if the compound is unsaturated, it is most preferred that the compound undergo a hydrogenation process to rupture or remove at least some of the double bonds. As used herein, the phrase “hydrogenation process” means that an unsaturated organic compound is reacted with hydrogen by either a direct addition of hydrogen to some or all of the double bonds, resulting in a saturated product (addition hydrogenation), or by rupturing the double bond entirely, whereby the fragments further react with hydrogen (hydrogenolysis). Examples of unsaturated rubbers and rubber compounds are polybutadiene, polyisoprene, polystyrene-butadiene and other unsaturated rubbers, rubber compounds or mixtures/combinations of rubber compounds.

As used herein, the term “compliant” encompasses the property of a material or a component that is yielding and formable, especially at about room temperature, as opposed to solid and unyielding at room temperature. As used herein, the term “crosslinkable” refers to those materials or compounds that are not yet crosslinked.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

More than one rubber compound of each type may be combined to produce a crosslinkable thermal interface component; however, it is contemplated that in the preferred thermal interface component, at least one of the rubber compounds or constituents will be a saturated compound. Olefin-containing or unsaturated thermal interface components, with appropriate thermal fillers, exhibit a thermal capability of less than 0.5° C.-cm²/W. Unlike thermal grease, thermal performance of the thermal interface component will not degrade after thermal cycling or flow cycling in IC devices because liquid olefins and liquid olefin mixtures (such as those comprising amine resins) will crosslink to form a soft gel upon heat activation. Moreover, when applied as a thermal interface component, it will not be “squeezed out” as thermal grease does in use and will not display interfacial delamination during thermal cycling.

Amine or amine-based resins are added or incorporated into the rubber composition or mixture of rubber compounds primarily to facilitate a crosslinking reaction between the amine resin and the primary or terminal hydroxyl groups on at least one of the rubber compounds. The crosslinking reaction between the amine resin and the rubber compounds produces a “soft gel” phase in the mixture, instead of a liquid state. The degree of crosslinking between the amine resin and the rubber composition and/or between the rubber compounds themselves will determine the consistency of the soft gel. For example, if the amine resin and the rubber compounds undergo a minimal amount of crosslinking (10% of the sites available for crosslinking are actually used in the crosslinking reaction) then the soft gel will be more “liquid-like”. However, if the amine resin and the rubber compounds undergo a significant amount of crosslinking (40-60% of the sites available for crosslinking are actually used in the crosslinking reaction and possibly there is a measurable degree of intermolecular or intramolecular crosslinking between the rubber compounds themselves) then the gel would become thicker and more “solid-like”.

Amine and amino resins are those resins that comprise at least one amine substituent group on any part of the resin backbone. Amine and amino resins are also synthetic resins derived from the reaction of urea, thiourea, melamine or allied compounds with aldehydes, particularly formaldehyde. Typical and contemplated amine resins are primary amine resins, secondary amine resins, tertiary amine resins, glycidyl amine epoxy resins, alkoxybenzyl amine resins, epoxy amine resins, melamine resins, alkylated melamine resins, and melamine-acrylic resins. Melamine resins are particularly useful and preferred in several contemplated embodiments described herein because a) they are ring-based compounds, whereby the ring contains three carbon and three nitrogen atoms, b) they can combine easily with other compounds and molecules through condensation reactions, c) they can react with other molecules and compounds to facilitate chain growth and crosslinking, d) they are more water resistant and heat resistant than urea resins, e) they can be used as water-soluble syrups or as insoluble powders dispersible in water, and f) they have high melting points (greater than 325° C. and are relatively non-flammable). Alkylated melamine resins, such as butylated melamine resins, propylated melamine resins, pentylated melamine resins hexylated melamine resins and the like, are formed by incorporating alkyl alcohols during the resin formation. These resins are soluble in paint and enamel solvents and in surface coatings.

Thermal filler particles to be dispersed in the thermal interface component or mixture should advantageously have a high thermal conductivity. Suitable filler materials include metals, such as silver, copper, aluminum, and alloys thereof; and other compounds, such as boron nitride, aluminum nitride, silver coated copper, silver-coated aluminum, conductive polymers and carbon fibers. Combinations of boron nitride and silver or boron nitride and silver/copper also provide enhanced thermal conductivity. Boron nitride in amounts of at least 20 wt % and silver in amounts of at least about 60 wt % are particularly useful. Preferably, fillers with a thermal conductivity of greater than about 20 and most preferably at least about 40 W/m° C. can be used. Optimally, it is desired to have a filler of not less than about 80 W/m° C. thermal conductivity.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include indium, silver, copper, aluminum, tin, bismuth, lead, gallium and alloys thereof, silver coated copper, and silver coated aluminum. The term “metal” also includes alloys, metal/metal composites, metal ceramic composites, metal polymer composites, as well as other metal composites. As used herein, the term “compound” means a substance with constant composition that can be broken down into elements by chemical processes.

Of special efficacy is a filler comprising a particular form of carbon fiber referred to as “vapor grown carbon fiber” (VGCF), such as is available from Applied Sciences, Inc., Cedarville, Ohio. VGCF, or “carbon micro fibers”, are highly graphized types by heat treatment (thermal conductivity=1900 W/m° C.). Addition of about 0.5 wt. % carbon micro fibers provides significantly increased thermal conductivity. Such fibers are available in varying lengths and diameters; namely, 0.05 millimeter (mm) to tens of centimeters (cm) length and from under 0.1 to over 100 μm in diameter. One useful form of VGCF has a diameter of not greater than about 1 μm and a length of about 50 to 100 μm, and possess a thermal conductivity of about two or three times greater than with other common carbon fibers having diameters greater than 5 μm.

It is difficult to incorporate large amounts of VGCF in polymer systems and interface components and systems, such as the hydrogenated rubber and resin combination already discussed. When carbon microfibers, e.g. (about 1 μm, or less) are added to the polymer they do not mix well, primarily because a large amount of fiber must be added to the polymer to obtain any significant beneficial improvement in thermal conductivity. However, we have discovered that relatively large amounts of carbon microfibers can be added to polymer systems that have relatively large amounts of other conventional fillers. A greater amount of carbon microfibers can be added to the polymer when added with other fibers, which can be added alone to the polymer, thus providing a greater benefit with respect to improving thermal conductivity of the thermal interface component. Desirably, the ratio of carbon microfibers to polymer is in the range of 0.05 to 0.50 by weight.

Once the thermal interface component that comprises at least one rubber compound, at least one amine resin, and at least one thermally conductive filler has been prepared, the composition must be compared to the needs of the electronic component, vendor, or electronic product to determine if an additional phase change material is needed to change some of the physical properties of the composition. Specifically, if the needs of the component or product require that the composition or interface material be in a “soft gel” form or a somewhat liquid form, then an additional phase change material may not need to be added. However, if the component, layered material or product requires that the composition or material be more like a solid, then at least one phase change material should be added.

Phase-change materials that are contemplated herein comprise waxes, polymer waxes or mixtures thereof, such as paraffin wax. Paraffin waxes are a mixture of solid hydrocarbons having the general formula CₙH₂ₙ₊₂ and having melting points in the range of about 20° C. to 100° C. Examples of some contemplated melting points are about 45° C. and 60° C. Thermal interface components that have melting points in this range are PCM45 and PCM60HD—both manufactured by Honeywell International Inc. Polymer waxes are typically polyethylene waxes, polypropylene waxes, and have a range of melting points from about 40° C. to 160° C.

PCM45 comprises a thermal conductivity of about 3.0 W/mK, a thermal resistance of about 0.25° C.-cm²/W, is typically applied at a thickness of about 0.0015 inches (0.04 mm) and comprises a soft material, flowing easily under an applied pressure of about 5 to 30 psi. Typical characteristics of PCM45 are a) a super high packaging density—over 80%, b) a conductive filler, c) extremely low thermal resistance, and as mentioned earlier d) about a 45° C. phase change temperature. PCM60HD comprises a thermal conductivity of about 5.0 W/mK, a thermal resistance of about 0.17° C.-cm²/W, is typically applied at a thickness of about 0.0015 inches (0.04 mm) and comprises a soft material, flowing easily under an applied pressure of about 5 to 30 psi. Typical characteristics of PCM60HD are a): a super high packaging density—over 80%, b) a conductive filler, c) extremely low thermal resistance, and as mentioned earlier d) about a 60° C. phase change temperature. TM350 (a thermal interface component not comprising a phase change material and manufactured by Honeywell International Inc.) comprises a thermal conductivity of about 3.0 W/mK, a thermal resistance of about 0.25° C.-cm²/W, is typically applied at a thickness of about 0.0015 inches (0.04 mm) and comprises a paste that can be thermally cured to a soft gel. Typical characteristics of TM350 are a) a super high packaging density—over 80%, b) a conductive filler, c) extremely low thermal resistance, d) about a 125° C. curing temperature, and e) dispensable non-silicone-based thermal gel.

Phase change materials are useful in thermal interface component applications because they are solid at room temperature and can easily be pre-applied to thermal management components. At operation temperatures above the phase change temperature, the material is liquid and behaves like a thermal grease. The phase change temperature is the melting temperature at which the heat absorption and rejection takes place.

Paraffin-based phase change materials, however, have several drawbacks. On their own, they can be very fragile and difficult to handle. They also tend to squeeze out of a gap from the device in which they are applied during thermal cycling, very much like grease. The rubber-resin modified paraffin polymer wax system described herein avoids these problems and provides significantly improved ease of handling, is capable of being produced in flexible tape or solid layer form, and does not pump out or exude under pressure. Although the rubber-resin-wax mixtures may have the same or nearly the same temperature, their melt viscosity is much higher and they do not migrate easily. Moreover, the rubber-wax-resin mixture can be designed to be self-crosslinking, which ensures elimination of the pump-out problem in certain applications. Examples of contemplated phase change materials are malenized paraffin wax, polyethylene-maleic anhydride wax, and polypropylene-maleic anhydride wax. The rubber-resin-wax mixtures will functionally form at a temperature between about 50 to 150° C. to form a crosslinked rubber-resin network.

It is also advantageous to incorporate additional fillers, substances or particles, such as filler particles, wetting agents or antioxidants into the thermal interface component. Substantially spherical filler particles can be added to the thermal interface component to maximize packing density. Additionally, substantially spherical shapes or the like will provide some control of the thickness during compaction. Typical particle sizes useful for fillers in the rubber material may be in the range of about 1-20 μm, about 21-40 μm, about 41-60 μm, about 61-80 μm, and about 81-100 μm with a maximum of about 100 μm.

Dispersion of filter particles can be facilitated by addition of functional organometallic coupling agents or “wetting” agents, such as organosilane, organotitanate, organozirconium, etc. Organotitanate acts a wetting enhancer to reduce paste viscosity and to increase filler loading. An organotitanate that can be used is isopropyl triisostearyl titanate. The general structure of organotitanate is RO—Ti(OXRY) where RO is a hydrolyzable group, and X and Y are binder functional groups.

Antioxidants may also be added to inhibit oxidation and thermal degradation of the cured rubber gel or solid thermal interface component. Typical useful antioxidants include Irganox 1076, a phenol type or Irganox 565, an amine type, (at 0.01% to about 1 wt. %), available from Ciba Giegy of Hawthorne, N.Y. Typical cure accelerators include tertiary amines such as didecylanethylamine, (at 50 ppm-0.5 wt. %).

At least one catalyst may also be added to the thermal interface component in order to promote a crosslinking or chain reaction between the at least one rubber compound, the at least one amine resin, the at least one phase change material, or all three. As used herein, the term “catalyst” means that substance or condition that notably affects the rate of a chemical reaction without itself being consumed or undergoing a chemical change. Catalysts may be inorganic, organic, or a combination of organic groups and metal halides. Although they are not substances, light and heat can also act as catalysts. In contemplated embodiments, the catalyst is an acid. In preferred embodiments, the catalyst is an organic acid, such as carboxylic, acetic, formic, benzoic, salicylic, dicarboxylic, oxalic, phthalic, sebacic, adipic, oleic, palmitic, stearic, phenylstearic, amino acids and sulfonic acid.

The contemplated thermal interface component can be provided as a dispensable liquid paste to be applied by dispensing methods (such as screen printing or stenciling) and then cured as desired. It can also be provided as a highly compliant, cured, elastomer film or sheet for pre-application on interface surfaces, such as heat sinks. It can further be provided and produced as a soft gel or liquid that can be applied to surfaces by any suitable dispensing method, such as screen-printing or ink jet printing. Even further, the thermal interface component can be provided as a tape that can be applied directly to interface surfaces or electronic components.

To illustrate several embodiments of the thermal interface components, a number of examples were prepared by mixing the following components: hydrogenated polybutylene mono-ol in 5 to 20 weight percent, hydrogenated polybutadiene diol in 0 to 5 weight percent, paraffin wax in 0 to 5 weight percent, alkylated melamine resin (butylated) in 0 to 5 weight percent, organotitanate in 1 to 10 weight percent, sulfonic acid catalyst in 0 to 1 weight percent, phenolic antioxidants in 0 to 1 weight percent, aluminum (metal-based) powder in 0 to 90 weight percent and boron nitride in 0 to 80 weight percent. These components may be formed in tape, paste, dispensable paste and liquid form. These components are described in U.S. Pat. No. 6,673,434, PCT Application Serial No.: PCT/US03/01094, PCT Application Serial No.: PCT/US03/19665, and U.S. application Ser. No. 10/242,139 filed in Sep. 9, 2002, all of which are commonly owned and incorporated herein by reference in their entirety.

These compounds also may include one or more of the optional additions, e.g., antioxidant, wetability enhancer, curing accelerators, viscosity reducing agents and crosslinking aids. The amounts of such additions may vary but, generally, they may be usefully present in the following approximate amounts (in wt. %): filler up to 95% of total (filler plus rubbers); wetability enhancer 0.1 to 1% (of total); antioxidant 0.01 to 1% (of total); curing accelerator 0.5% (of total); viscosity reducing agents 0.2-15%; and crosslinking aids 0.1-2%. It should be noted the addition at least about 0.5% carbon fiber significantly increases thermal conductivity.

Another suitable thermal interface material can also be produced/prepared that comprises a resin mixture and at least one solder material. The resin material may comprise any suitable resin material, but it is preferred that the resin material be silicone-based comprising one or more compounds such as vinyl silicone, vinyl Q resin, hydride functional siloxane and platinum-vinylsiloxane. The solder material may comprise any suitable solder material or metal, such as indium, silver, copper, aluminum, tin, bismuth, lead, gallium and alloys thereof, silver coated copper, and silver coated aluminum, but it is preferred that the solder material comprise indium or indium-based alloys.

The solder-based interface materials, such a polymer solder materials, polymer solder hybrid materials and other solder-based interface materials, as described herein, have several advantages directly related to use and component engineering, such as: a) the interface material/polymer solder material can be used to fill small gaps on the order of 2 millimeters or smaller, b) the interface material/polymer solder material can efficiently dissipate heat in those very small gaps as well as larger gaps, unlike most conventional solder materials, and

c) the interface material/polymer solder material can be easily incorporated into micro components, components used for satellites, and small electronic components.

Resin-containing interface materials and solder materials, especially those comprising silicone resins, that may also have appropriate thermal fillers can exhibit a thermal capability of less than 0.5° C.-cm²/W. Unlike thermal grease, thermal performance of the material will not degrade after thermal cycling or flow cycling in IC devices because liquid silicone resins will cross link to form a soft gel upon heat activation.

Interface materials and polymer solders comprising resins, such as silicone resins, will not be “squeezed out” as thermal grease can be in use and will not display interfacial delamination during thermal cycling. The new material can be provided as a dispensable liquid paste to be applied by dispensing methods and then cured as desired. It can also be provided as a highly compliant, cured, and possibly cross-linkable elastomer film or sheet for pre-application on interface surfaces, such as heat sinks. Advantageously, fillers with a thermal conductivity of greater than about 20 and preferably at least about 40 W/m° C. will be used. Optimally, it is desired to have a filler of not less than about 100 W/m° C. thermal conductivity. The interface material enhances thermal dissipation of high power semiconductor devices. The paste may be formulated as a mixture of functional silicone resins and thermal fillers.

A vinyl Q resin is an activated cure specialty silicone rubber having the following base polymer structure:

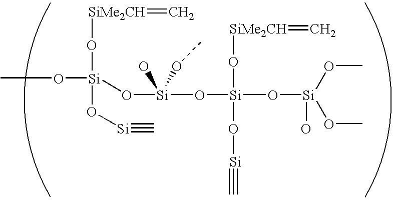

Vinyl Q resins are also clear reinforcing additives for addition cure elastomers. Examples of vinyl Q resin dispersions that have at least 20% Q-resin are VQM-135 (DMS-V41 Base), VQM-146 (DMS-V46 Base), and VQX-221 (50% in xylene Base).

As an example, a contemplated silicone resin mixture could be formed as follows:

| Component | % by weight | Note/Function |
|---|---|---|
| Vinyl silicone | 75 (70-97 range) | Vinyl terminated siloxane |
| Vinyl Q Resin | 20 (0-25 range) | Reinforcing additive |
| Hydride functional | 5 (3-10 range) | Crosslinker |
| siloxane | | |
| Platinum-vinylsiloxane | 20-200 ppm | Catalyst |

The resin mixture can be cured at either at room temperature or at elevated temperatures to form a compliant elastomer. The reaction is via hydrosilylation (addition cure) of vinyl functional siloxanes by hydride functional siloxanes in the presence of a catalyst, such as platinum complexes or nickel complexes. Preferred platinum catalysts are SIP6830.0, SIP6832.0, and platinum-vinylsiloxane.

Contemplated examples of vinyl silicone include vinyl terminated polydimethyl siloxanes that have a molecular weight of about 10000 to 50000. Contemplated examples of hydride functional siloxane include methylhydrosiloxane-dimethylsiloxane copolymers that have a molecular weight about 500 to 5000. Physical properties can be varied from a very soft gel material at a very low crosslink density to a tough elastomer network of higher crosslink density.

Solder materials that are dispersed in the resin mixture are contemplated to be any suitable solder material for the desired application. Preferred solder materials are indium tin (InSn) alloys, indium silver (InAg) alloys, indium-bismuth (InBi) alloys, indium-based alloys, tin silver copper alloys (SnAgCu), tin bismuth and alloys (SnBi), and aluminum-based compounds and alloys. Especially preferred solder materials are those materials that comprise indium. The solder may or may not be doped with additional elements to promote wetting to the heat spreader or die backside surfaces.

As with the previously described thermal interface materials and components, thermal filler particles may be dispersed in the resin mixture. If thermal filler particles are present in the resin mixture, then those filler particles should advantageously have a high thermal conductivity. Suitable filler materials include silver, copper, aluminum, and alloys thereof; boron nitride, aluminum spheres, aluminum nitride, silver, coated copper, silver coated aluminum, carbon fibers, and carbon fibers coated with metals, metal alloys, conductive polymers or other composite materials. Combinations of boron nitride and silver or boron nitride and silver/copper also provide enhanced thermal conductivity. Boron nitride in amounts of at least 20 wt. %, aluminum spheres in amounts of at least 70 wt. %, and silver in amounts of at least about 60 wt. % are particularly useful. These materials may also comprise metal flakes or sintered metal flakes.

Vapor grown carbon fibers, as previously described, and other filters, such as substantially spherical filler particles may be incorporated. Additionally, substantially spherical shapes or the like will also provide some control of the thickness during compaction. Dispersion of filler particles can be facilitated by the addition of functional organo metallic coupling agents or wetting agents, such as organosilane, organotitanate, organozirconium, etc. The organo metallic coupling agents, especially organotitanate, may also be used to facilitate melting of the solder material during the application process. Typical particle sizes useful for fillers in the resin material may be in the range of about 1-20 μm with a maximum of about 100 μm.

These compounds may comprise at least some of the following: at least one silicone compound in 1 to 20 weight percent, organotitanate in 0-10 weight percent, at least one solder material in 5 to 95 weight percent. These compounds may include one or more of the optional additions, e.g., wetability enhancer. The amounts of such additions may vary but, generally, they may be usefully present in the following approximate amounts (in wt. %): filler up to 95% of total (filler plus resins); wetability enhancer 0.1 to 5% (of total); and adhesion promoters 0.01 to 1% (of total). It should be noted the addition at least about 0.5% carbon fiber significantly increases thermal conductivity. These compositions are described in U.S. Pat. No. 6,706,219, U.S. application Ser. No. 10/775,989 filed on Feb. 9, 2004 and PCT Serial No.: PCT/US02/14613, which are all commonly owned and incorporated herein in their entirety by reference.

Contemplated solder compositions are as follows: InSn=52% In (by weight) and 48% Sn (by weight) with a melting point of 118° C.; InAg=97% In (by weight) and 3% Ag (by weight) with a melting point of 143° C.; In =100% indium (by weight) with a melting point of 157° C.; SnAgCu=94.5% tin (by weight), 3.5% silver (by weight) and 2% copper (by weight) with a melting point of 217° C.; SnBi=60% Tin (by weight) and 40% bismuth (by weight) with a melting point of 170° C. It should be appreciated that other compositions comprising different component percentages can be derived from the subject matter contained herein.

Another suitable interface material can also be produced/prepared that comprises a solder material. The solder material may comprise any suitable solder material or metal, such as indium, silver, copper, aluminum, tin, bismuth, lead, gallium and alloys thereof, silver coated copper, and silver coated aluminum, but it is preferred that the solder material comprise indium or indium-based alloys. Suitable interface materials may comprise a conductive filler, a metallic material, a solder alloy and combinations thereof.

The solder-based interface materials, as described herein, have several advantages directly related to use and component engineering, such as: a) high bulk thermal conductivity, b) metallic bonds may be formed at the joining surfaces, lower contact resistance c) the interface solder material can be easily incorporated into micro components, components used for satellites, and small electronic components.

An additional component, such as a low modulus metal coated polymer sphere or microspheres may be added to the solder material to decrease the bulk elastic modulus of the solder.

An additional component may also be added to the solder to promote wetting to the die and/or heat spreader surface. These additions are contemplated to be silicide formers, or elements that have a higher affinity for oxygen or nitrogen than does silicon. The additions can be one element that satisfies all requirements, or multiple elements each of which has one advantage. Additionally, alloying elements may be added which increase the solubility of the dopant elements in the indium or solder matrix.

Heat spreader components or heat spreading components (heat spreader and heat spreading are used herein interchangeably and have the same common meaning) generally comprise a metal, a metal-based base material, a high-conductivity non-metal or combinations thereof, such as nickel, aluminum, copper, copper-tungsten, CuSiC, diamond, silicon carbide, graphite, composite materials such as copper composites, carbon composites and diamond composites or AlSiC and/or other suitable high-conductivity materials that may not comprise metal. Any suitable metal or metal-based base material can be used herein as a heat spreader, as long as the metal or metal-based base material can dissipate some or all of the heat generated by the electronic component. Specific examples of contemplated heat spreader components are shown under the Examples section.

Heat spreader components can be laid down in any suitable thickness, depending on the needs of the electronic component, the vendor and as long as the heat spreader component is able to sufficiently perform the task of dissipating some or all of the heat generated from the surrounding electronic component. Contemplated thicknesses comprise thicknesses in the range of about 0.25 mm to about 6 mm. In some embodiments, contemplated thicknesses of heat spreader components are within the range of about 0.5 mm to about 5 mm. In other embodiments, contemplated thicknesses of heat spreader components are within the range of about 1 mm to about 4 mm.

When using a metallic thermal interface material, like solder, which has a high elastic modulus compared to most polymer systems, it may be necessary to reduce coefficient of thermal expansion mismatch generated mechanical stresses transferred to the semiconductor die in order to prevent cracking of the die. This stress transfer can be minimized by increasing the bondline of the metallic thermal interface material, reducing the coefficient of thermal expansion of the heat spreader, or change the geometry of the heat spreader to minimize stress transfer. Examples of lower coefficient of thermal expansion (CTE) materials are AlSiC, CuSiC, copper-graphite composites, carbon-carbon composites, diamond, CuMoCu laminates, etc. Examples of geometric changes are adding a partial or through slot to the spreader to decrease spreader thickness and forming a truncated, square based, inverted pyramid shape to lower stress and stiffness by having the spreader cross-section be lower near the semiconductor die.

Applications of the contemplated thermal solutions, IC Packages, layered interface materials, thermal interface components and heat spreader components described herein comprise incorporating the materials into a layered material, a layered component, an electronic component, a semiconductor component, a finished electronic product or a finished semiconductor product.

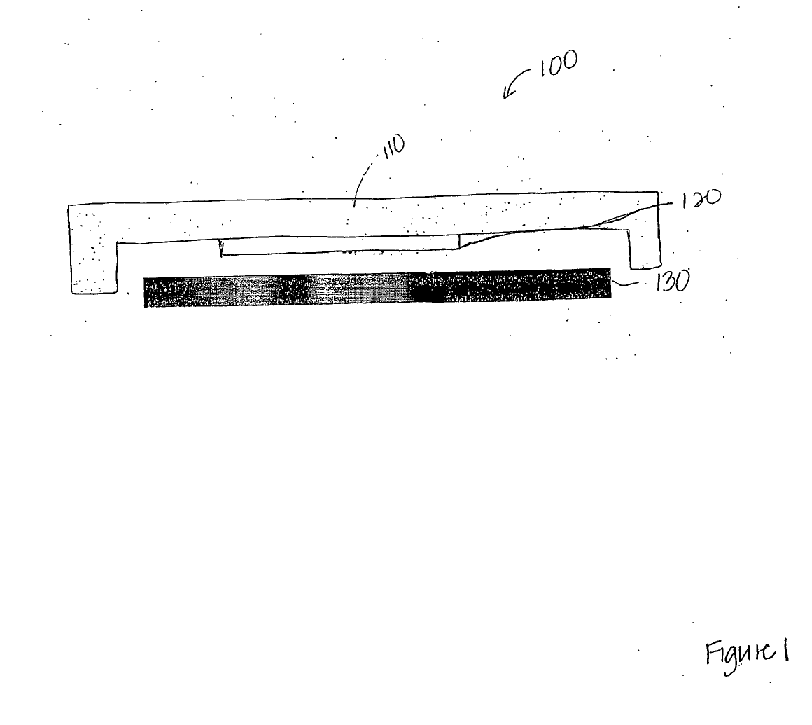

Pre-attached/pre-assembled thermal solutions and/or IC (interconnect) packages comprise one or more components of the thermal interface materials described herein and at least one adhesive component. Several of the contemplated pre-attached/pre-assembled thermal solutions/IC Packages are shown in FIGS. 1, 5, 7, 9 and 11-18 and are discussed in detail in the Examples Section. It should be understood that there are many other embodiments that are contemplated and that can be assembled given the disclosure presented herein. These thermal interface materials exhibit low thermal resistance for a wide variety of interface conditions and demands. As used herein, the term “adhesive component” means any substance, inorganic or organic, natural or synthetic, that is capable of bonding other substances together by surface attachment. In some embodiments, the adhesive component may be added to or mixed with the thermal interface material, may actually be the thermal interface material or may be coupled, but not mixed, with the thermal interface material. Examples of some contemplated adhesive components comprise double-sided tape from SONY, such as SONY T4411, 3M F9460PC or SONY T4100D203. In other embodiments, the adhesive may serve the additional function of attaching the heat spreading component to the package substrate independent of the thermal interface material, as indicated in FIG. 11.

The thermal interface components, the crosslinkable thermal interface components and the heat spreader components can be individually prepared and provided by using the methods previously described herein. The two components are then physically coupled to produce a layered interface material. As used herein, the term “interface” means a couple or bond that forms the common boundary between two parts of matter or space. An interface may comprise a physical attachment or physical couple of two parts of matter or components or a physical attraction between two parts of matter or components, including bond forces such as covalent and ionic bonding, and non-bond forces such as Van der Waals, electrostatic, coulombic, hydrogen bonding and/or magnetic attraction. The two components, as described herein, may also be physically coupled by the act of applying one component to the surface of the other component.

The layered interface material may then be applied to a substrate, another surface, or another layered material. The electronic component comprises a layered interface material, a substrate layer and an additional layer. The layered interface material comprises a heat spreader component and a thermal interface component. Substrates contemplated herein may comprise any desirable substantially solid material. Particularly desirable substrate layers would comprise films, glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polymimide. The “substrate” may even be defined as another polymer material when considering cohesive interfaces. In more preferred embodiments, the substrate comprises a material common in the packaging and circuit board industries such as silicon, copper, glass, and another polymer.

Additional layers of material may be coupled to the layered interface materials in order to continue building a layered component or printed circuit board. It is contemplated that the additional layers will comprise materials similar to those already described herein, including metals, metal alloys, composite materials, polymers, monomers, organic compounds, inorganic compounds, organometallic compounds, resins, adhesives and optical wave-guide materials.

A layer of laminating material or cladding material can be coupled to the layered interface materials depending on the specifications required by the component. Laminates are generally considered fiber-reinforced resin dielectric materials. Cladding materials are a subset of laminates that are produced when metals and other materials, such as copper, are incorporated into the laminates. (Harper, Charles A., Electronic Packaging and Interconnection Handbook, Second Edition, McGraw-Hill (New York), 1997.)

Spin-on layers and materials may also be added to the layered interface materials or subsequent layers. Spin-on stacked films are taught by Michael E. Thomas, “Spin-On Stacked Films for Low k_{eff} Dielectrics”, Solid State Technology (July 2001), incorporated herein in its entirety by reference.

Applications of the contemplated thermal solutions, IC Packages, thermal interface components, layered interface materials and heat spreader components described herein comprise incorporating the materials and/or components into another layered material, an electronic component or a finished electronic product. Electronic components, as contemplated herein, are generally thought to comprise any layered component that can be utilized in an electronic-based product. Contemplated electronic components comprise circuit boards, chip packaging, separator sheets, dielectric components of circuit boards, printed-wiring boards, and other components of circuit boards, such as capacitors, inductors, and resistors.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up/mock-up. A prototype may or may not contain all of the actual components intended in a finished product, and a prototype may have some components that are constructed out of composite material in order to negate their initial effects on other components while being initially tested.

### EXAMPLES

The following examples show a basic procedure and testing mechanism for pre-assembling the thermal interface materials and layered material according to the subject matter disclosed herein, and the testing parameters and discussion uses nickel-plated copper as a heat spreader component. However, it should be understood that any suitable heat spreader component can be used for this application and layered material. Also, PCM 45 is used herein in the examples as a representative thermal interface material component, however, it should be understood that any suitable phase change material component can be used according to the subject matter disclosed herein.

### Example 1

Basic Procedure for Assembly

Material

Heat Spreader Component

Suitable phase change material per specifications of the vendor and/or manufacturer.

Fixturing (specific fixturing, preferably nylon, for the component and PCM material)

Instructions

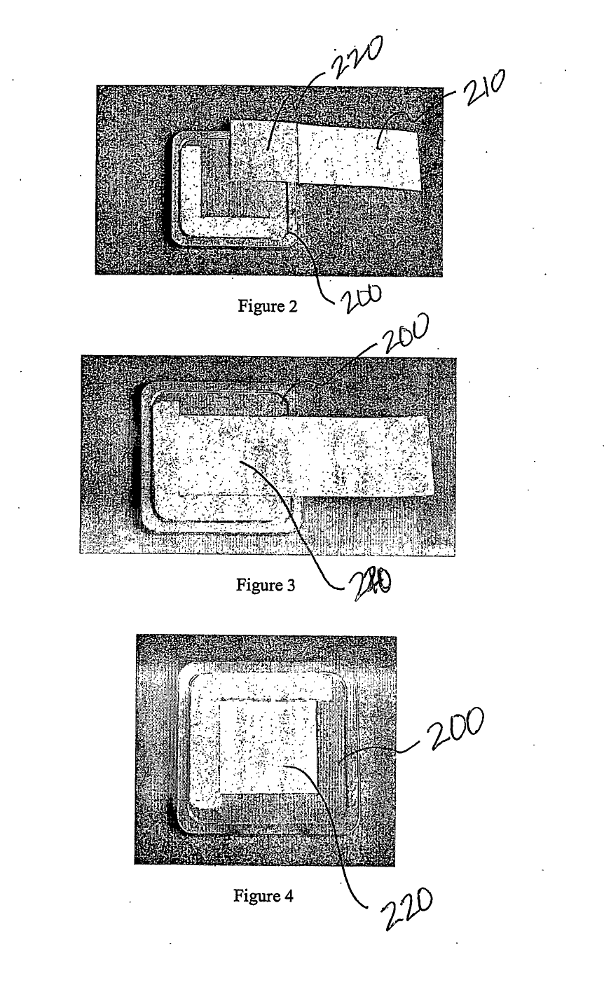

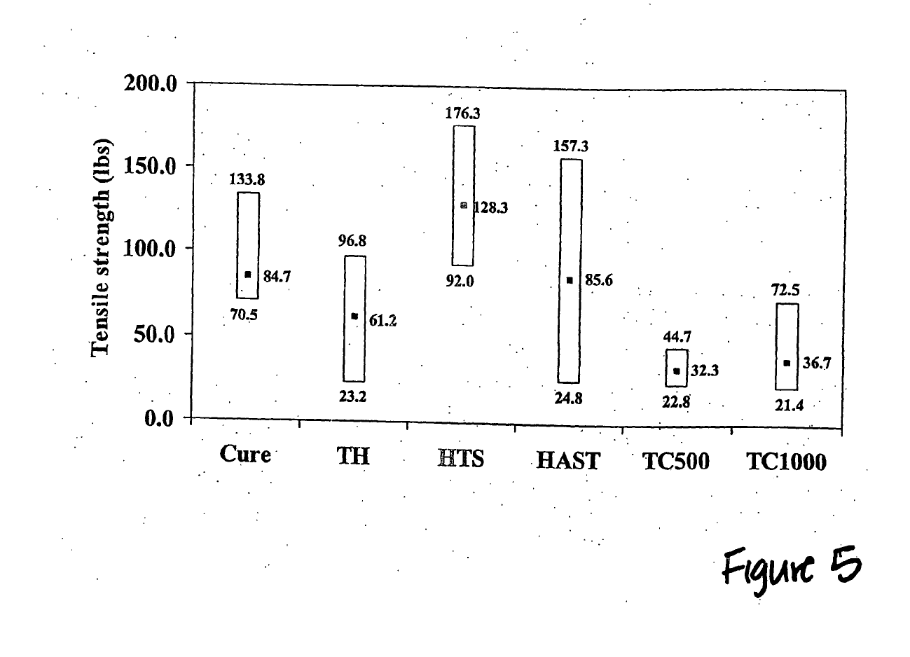

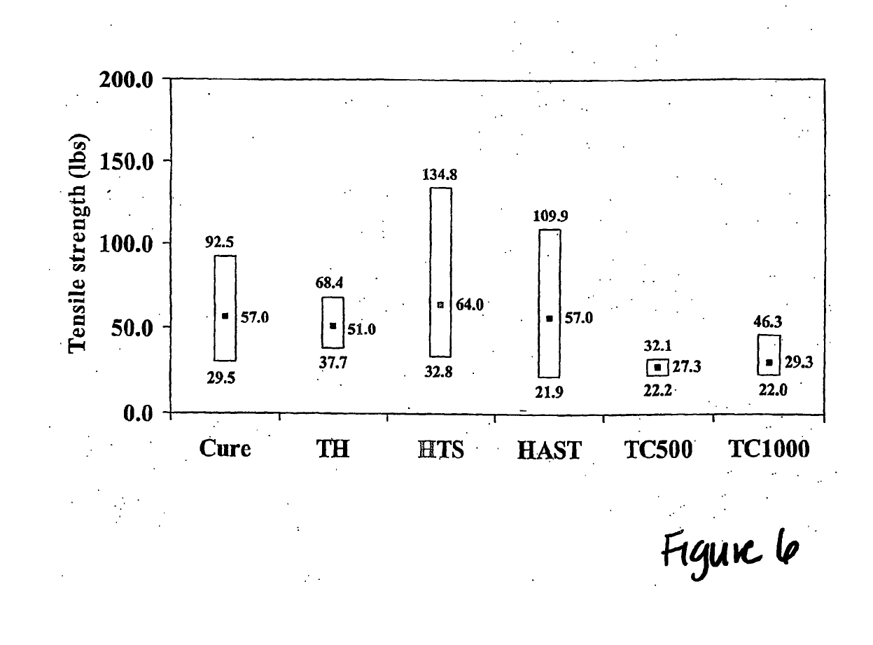

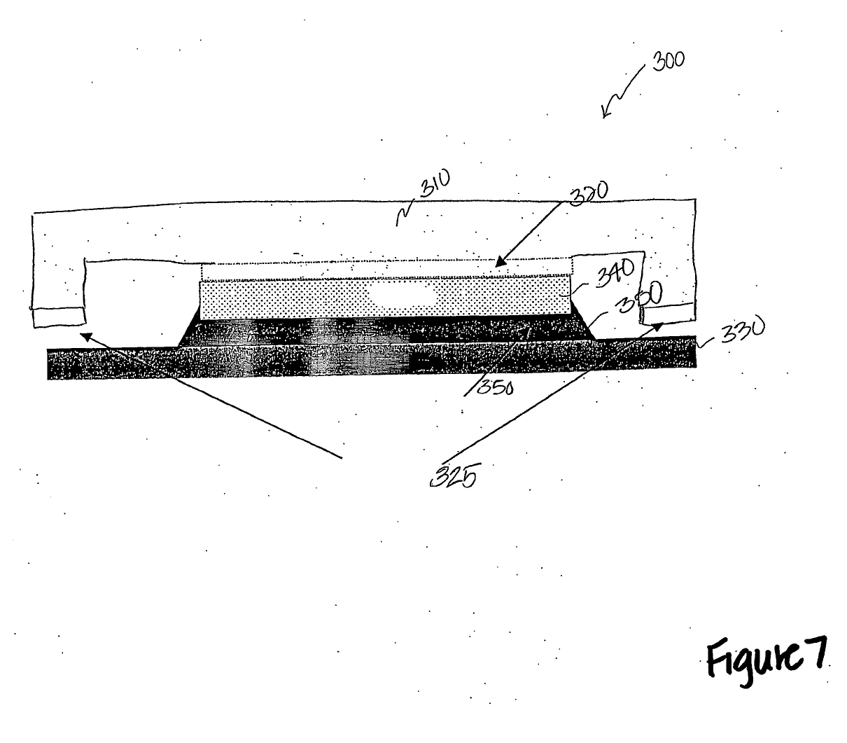

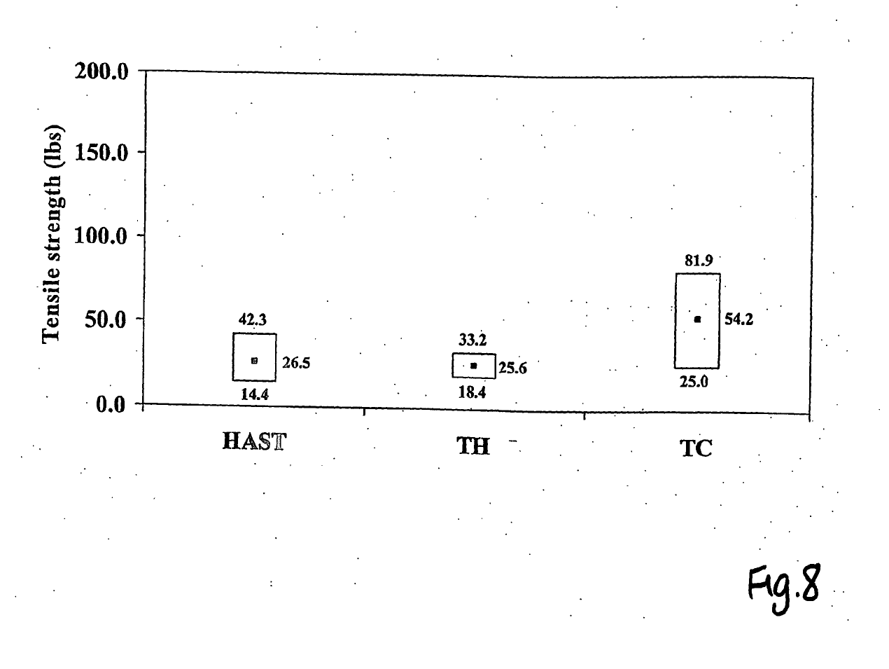

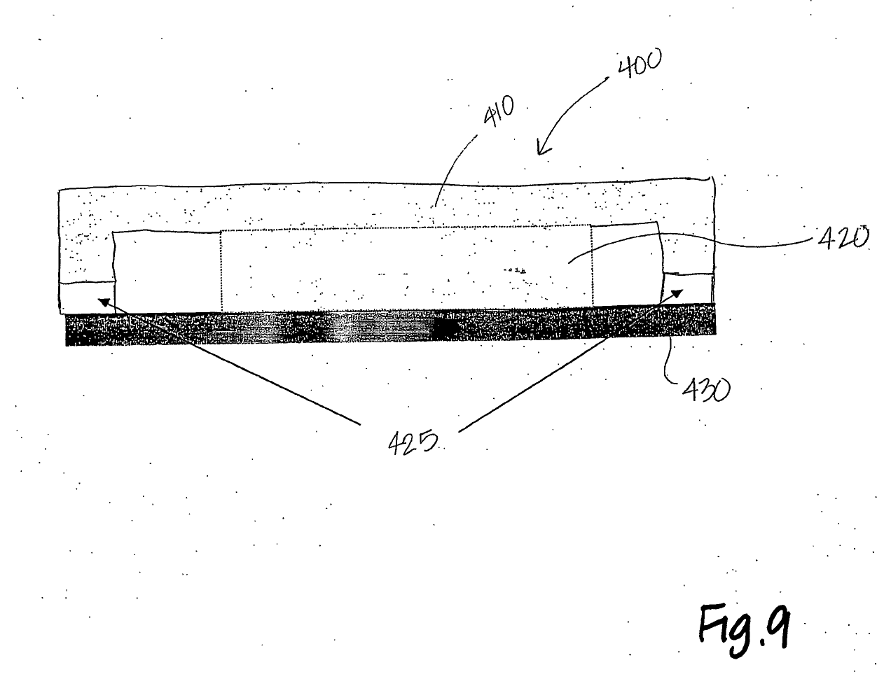

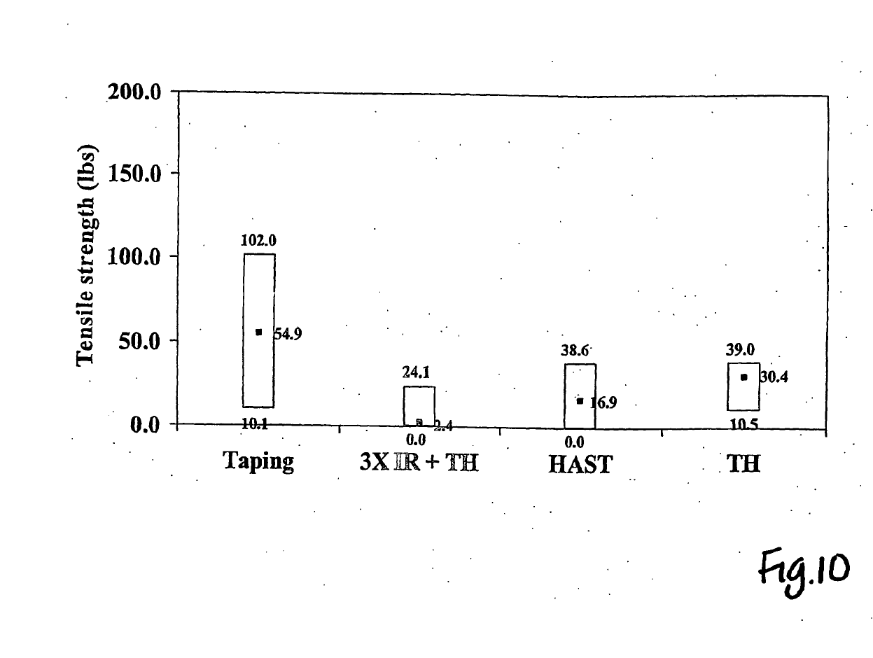

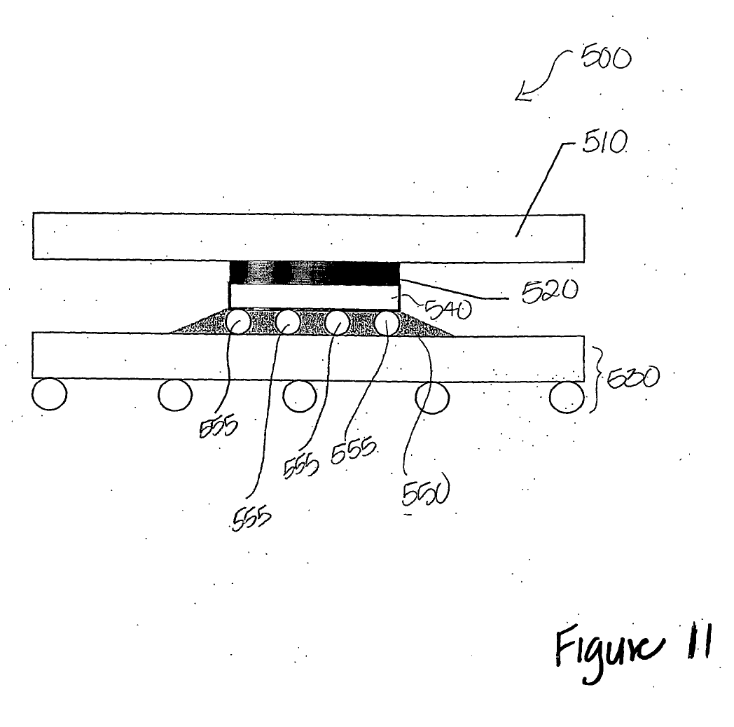

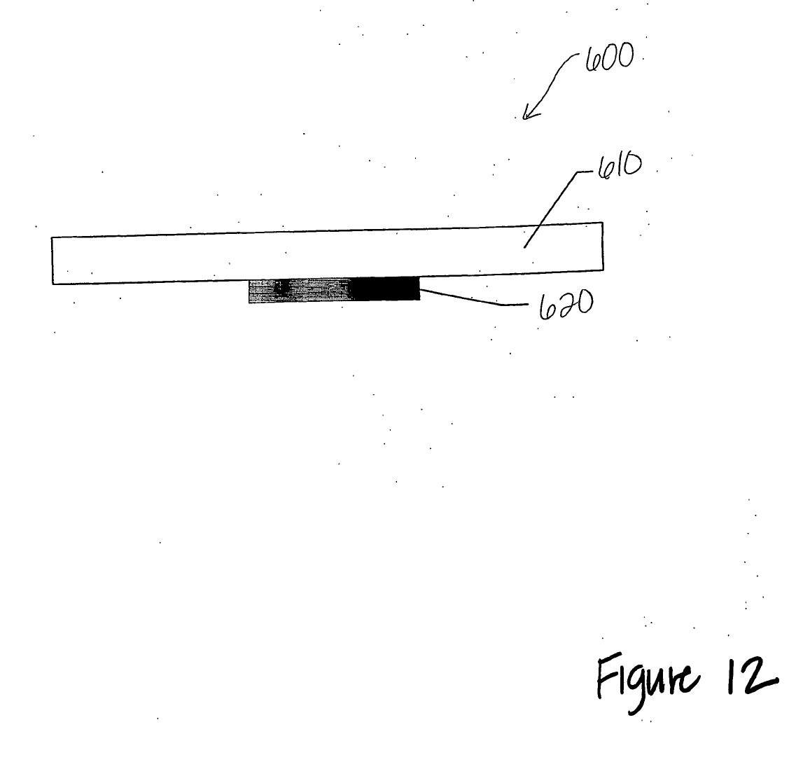

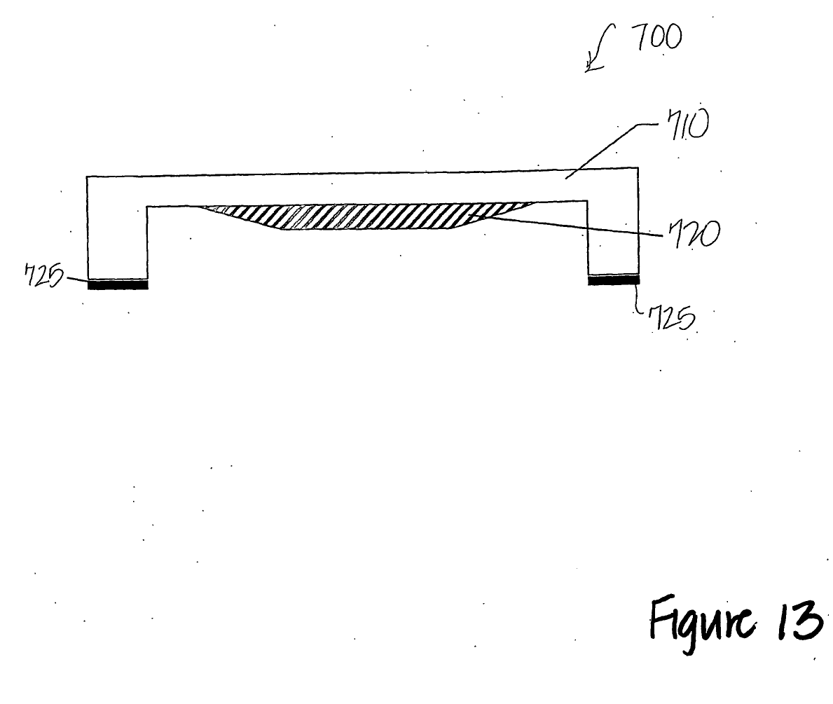

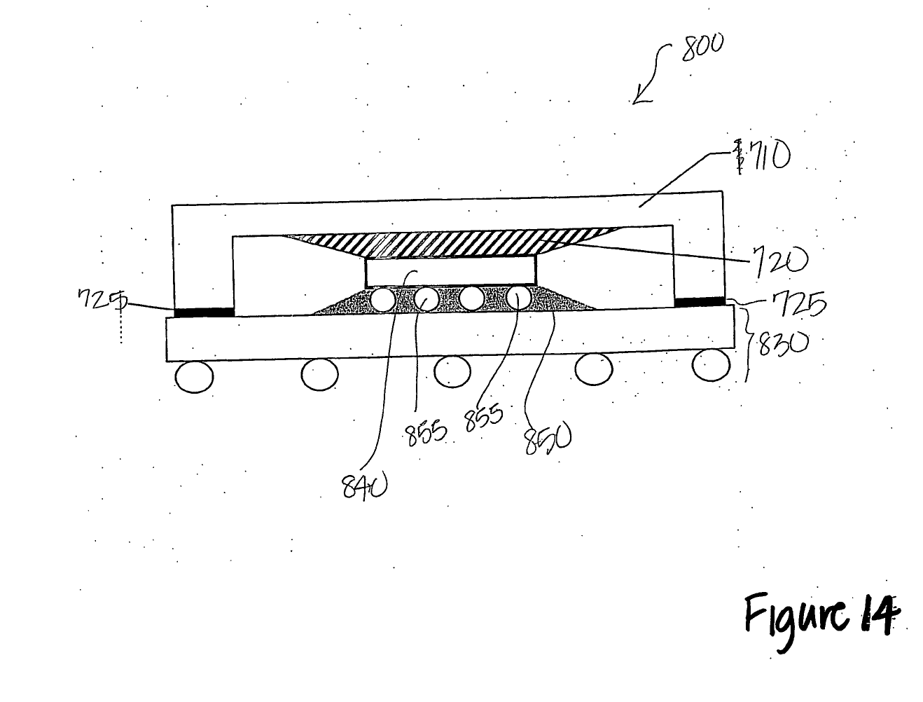

Pull a 32 piece random sample of the component for outgoing inspection prior to applying PCM material.
Start with Room temp. phase change material, such as PCM 45. If the both top and bottom release liners fall off prematurely, warm the PCM material for >0.5 hr at 30° C.
Ensure that the substrate temperature is greater than 21° C.
Apply the phase change material to component per the following instructions:
   The release liner 210 is removed to expose the phase change material 220 to apply the material 220 to the component 200 as per FIG. 2
   Locate the alignment jig on the component, apply the phase change material 220 to the component 200 with light finger pressure as per FIGS. 3 and 4
   Run through heat tunnel to bring the combination part to an exit temperature of between 48° C. and 60° C. Residence time can be from 30 to 60 seconds.
   Apply light finger pressure to PCM 45 to ensure complete attachment
Refrigerate to less than −10° C. for greater than ten minutes
Remove top liner
Visually inspect combination part for defects
Load into trays
   Dimensional and Heat Spreader Component (Nickel) Thickness Standards
   Sample Sizes: 1 out of every 1,500 pieces (Dimensional and X-Ray Fluorescence (XRF) measurements) CMM=Coordinate Measurement Machine

0.10 AQL, C=0 (Visual)

TABLE 1
Dimensional and Nickel Thickness Requirements

| Parameter | Metrology | Criteria/Disposition | Cpk |
|---|---|---|---|
| Outside Length/Width | CMM | 37.5 ± 0.05 mm | 1.33 |
| | (touch or optical) | | |
| Flange Width | CMM | 2.5 ± 0.15 mm | 1.33 |
| | (touch or optical) | | |
| Cavity Depth | CMM (touch or optical) | 0.60 ± 0.025 mm | 1.33 |
| Overall Thickness | Micrometer | 3.0 ± 0.1 mm | 1.33 |
| Flatness (Topside) | CMM (optical or touch) | 9 point array | 1.33 |
| | .035 mm max | | |
| | 2 mm from edge | | |
| Flatness (Cavity) | CMM (optical or touch) | 9 point array | 1.33 |
| | .025 mm max in | | |
| | 22 mm sq. area | | |
| | in center. | | |
| Nickel Thickness | XRF | 3 to 10 μm | 1.33 |
| @ Center of Top Side | | | |
| Flange Surface Roughness | Profilometer, | Less than 1 μm | NA |
| | 2.5 cm stroke | | |
| PCM45 Attached Thickness | Linear Measurement | 0.25 mm ± 0.06 mm | NA |
| | Tools | | |
| PCM45 Attached Length/Width | Linear Measurement | 20 mm ± 2.0 mm | 1.33 |
| | Tools | | |
| PCM45 Location | Mask | Located within center | NA |
| | | 23 mm area of cavity | |
| PCM45 Thermal Impedance | ASTM D5470 | ≦0.35 Ccm²/W | 1.33 |
| (Measured on bulk sample) | | at 30 psi and | |
| | | 0.001″ ≦ BLT ≦ 0.002″ | |
| PCM45 Phase Change | DSC | 45° C. +/− 8° C. | 1.33 |
| (peak Temperature, Measured on | (@N₂, 5° C./min) | | |
| bulk material) | | | |

Storage Condition and Shelf Life

Final Parts shall be kept in sealed bag at about room temperature (25° C.±5° C.). Avoid excess heat (more than 40° C.) and direct sun exposure or extreme cold (less than 5° C.). Do not apply more than about 5 psi pressure to exposure phase change material (PCM) surface. Shelf life is about 1 year from product manufacture.

As discussed herein, the thermal interconnect system, thermal interface and interface materials are beneficial for many reasons. One reason is that the heat spreader component and interface material has excellent wetting at the interface between the heat spreader component and the interface material, and this interfacial wetting is able to withstand the most extreme conditions. A second reason is that the heat spreader component/thermal interface material combination disclosed and discussed herein reduces the number of steps necessary for package assembly by the customer—given that its pre-assembled and quality checked before the customer receives it. The pre-assembly of the component also reduces the associated costs on the part of the customer. A third reason is that the heat spreader component and the thermal interface material can be designed to “work together”, so that the interfacial thermal resistance is minimized for the specific combination of heat spreader component and thermal interface material.

### Example 2

As mentioned earlier, pre-attached/pre-assembled thermal solutions and/or IC (interconnect) packages comprise one or more components of the thermal interface materials described herein and optionally at least one adhesive component. A contemplated pre-attached/pre-assembled thermal solution is shown in FIG. 1. FIG. 1 shows a thermal transfer material 100 which comprises a heat spreader component 110, a thermal interface component 120 and a substrate 130. Thermal interface component 120 may comprise a thermal interface material and/or a thermal interface material coupled with or combined with an adhesive material. As mentioned, the thermal interface component 120 may be in the form of a tape, a paste, a dispensable paste or a liquid. The adhesive component described in these figures was cut to 10 mm by 10 mm and placed between the substrate/surface and the heat spreader. The adhesion strength of the tape was measured before and after preconditioning.

Data showing the incorporation of some of the contemplated adhesive components, one of which is shown in FIG. 1, are shown in FIGS. 5 and 6. In these figures, tensile strength is shown for several conditions while using a thermal interface component in the form of a tape. In both figures, “Cure” stands for after cure, “TH” stands for after temperature and humidity, which comprises holding the material at a specific temperature and a specific relative humidity for a prescribed period of time (for example, 85 C at 85% relative humidity for 168 hours), “HTS” stands for after high temperature storage, which comprises storage of the material at a specific temperature or a prescribed period of time (for example, 125 C for 500 hours), “HAST” stands for after high temperature and humidity, which comprises holding the material at a specific high temperature and a specific relative humidity for a prescribed period of time (for example, 130 C at 85% relative humidity for 96 hours), “TC500” stands for temperature cycling for 500 cycles, “TC1000” stands for temperature cycling for 1000 cycles. These abbreviations are also used in other figures and should be considered the same as those above described.

FIG. 7 shows another contemplated pre-attached/pre-assembled thermal solution and/or material. FIG. 7 shows a thermal transfer material 300 which comprises a heat spreader component 310, a thermal interface component 320, an adhesive component 325 and a substrate 330. Thermal interface component 320 may comprise a thermal interface material and/or a thermal interface material coupled with or combined with an adhesive material. As mentioned, the thermal interface component 320 may be in the form of a tape, a paste, a dispensable paste or a liquid. In this contemplated embodiment, a die 340 and an underfill material 350 is also included in the thermal transfer material 300. The adhesion strength of the adhesive component was evaluated after preconditioning. The adhesive component in this embodiment is in the form of a tape that was cut to cover the outer ring of the heat spreader component 310. FIG. 8 shows the data collected from this contemplated embodiment.

FIG. 9 shows yet another contemplated embodiment of the pre-attached/pre-assembled thermal solution. FIG. 9 shows a thermal transfer material 400 which comprises a heat spreader component 410, a thermal interface component 420, an adhesive component 425 and a substrate 430. Thermal interface component 420 may comprise a thermal interface material and/or a thermal interface material coupled with or combined with an adhesive material. As mentioned, the thermal interface component 420 may be in the form of a tape, a paste, a dispensable paste or a liquid. Each of the adhesive components was cut to cover the outer ring of the heat spreader. The adhesion strength of each of the adhesive and/or thermal components was measured before and after preconditioning. FIG. 10 shows the data collected from these contemplated embodiments.

FIGS. 11-18 show several types of these contemplated layered materials that comprise at least one heat spreader, at least one thermal interface material, a substrate and in some cases at least one adhesive component. In FIG. 11, a thermal transfer material 500 is shown that comprises a heat spreader component 510, a thermal interface component 520 that is in the form of a tape, a die 540 and an underfill material 550 that comprises solder balls 555. The thermal transfer material further comprises a substrate 530. FIG. 12 shows another contemplated embodiment of a thermal transfer material as used in an IC package 600 which comprises a heat spreader component 610 and a thermal interface component 620 that is in the form of a tape. This thermal transfer material 600 may also be incorporated into the thermal transfer material 500 of FIG. 11.

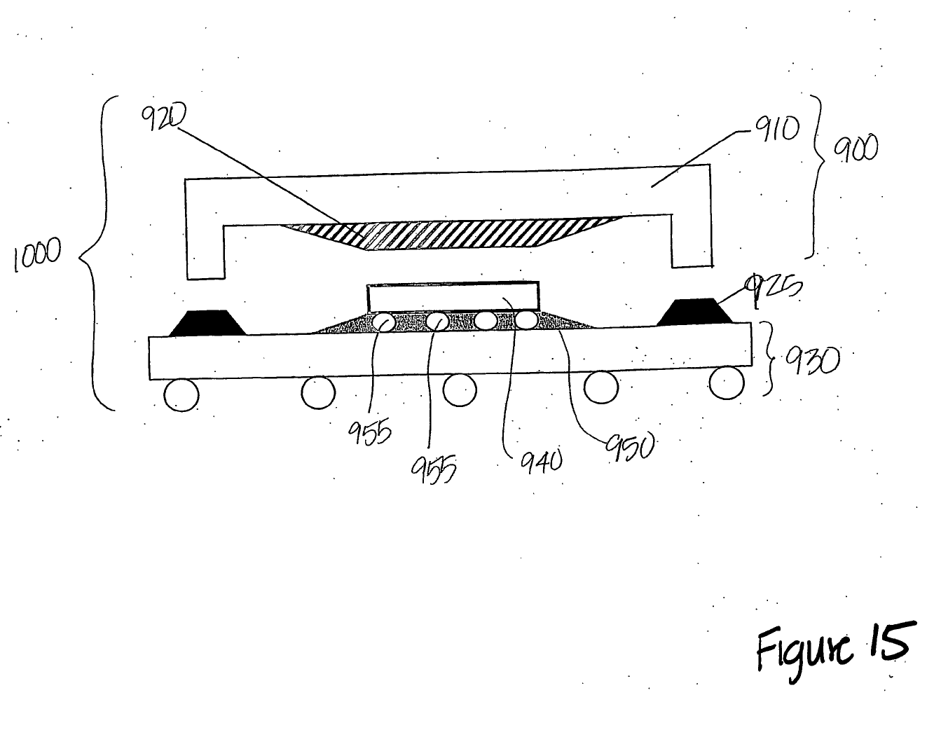

FIGS. 13 and 14 show another contemplated embodiment of a thermal transfer material 700 and how it is used in an IC package 800. FIG. 13 shows a thermal transfer material 700 which comprises a heat spreader component 710 and a thermal interface component 720, which may comprise a phase change material, a tape, a gel or any other suitable thermal interface material. This embodiment also comprises an adhesive component 725, which in this case may be a high temperature adhesive tape. In FIG. 14, the thermal transfer material 700 is coupled to a die 840, an underfill material 850, which comprises solder material 855, and a substrate 830.

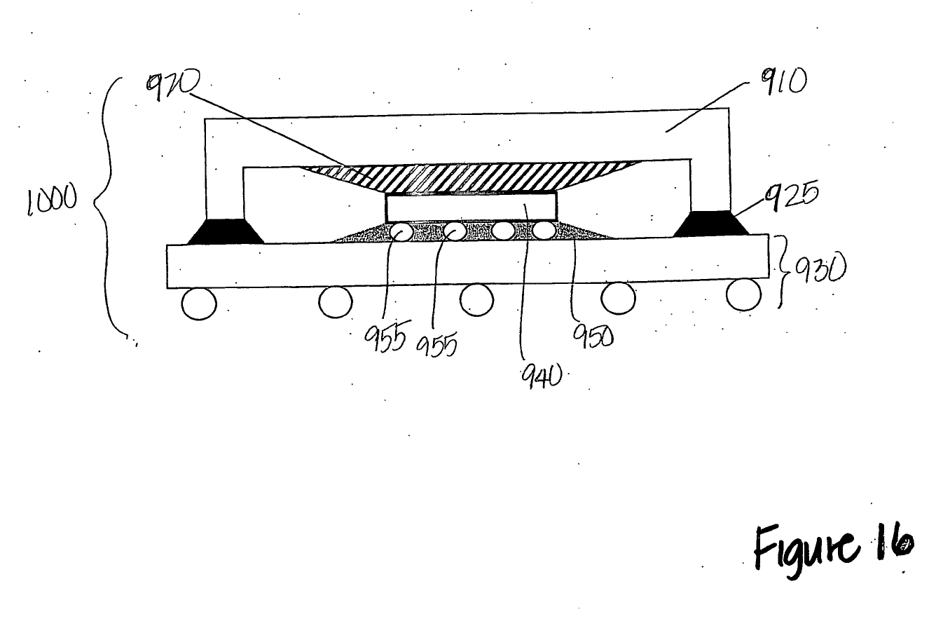

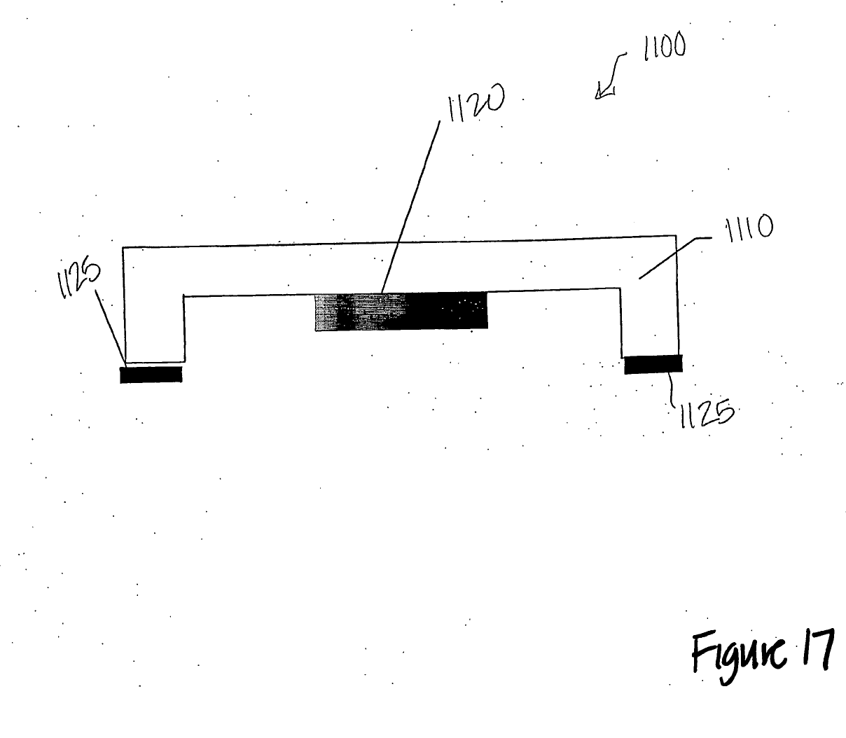

FIGS. 15 and 16 show another contemplated embodiment of a thermal transfer material 900 and how it is used in an IC package 1000. FIG. 15 shows a thermal transfer material 900 which comprises a heat spreader component 910 and a thermal interface component 920, which may comprise a phase change material, a tape, a gel or any other suitable thermal interface material. This embodiment also comprises an adhesive component 925, which in this case may be a high temperature adhesive tape or structural tape, but the adhesive component is not part of the heat spreader component/thermal interface component couple 900. In FIG. 16, the thermal transfer material 900 is coupled to a die 940, an underfill material 950, which comprises solder material 955, and a substrate 930. The adhesive component 925 in this embodiment is located on the substrate 930.

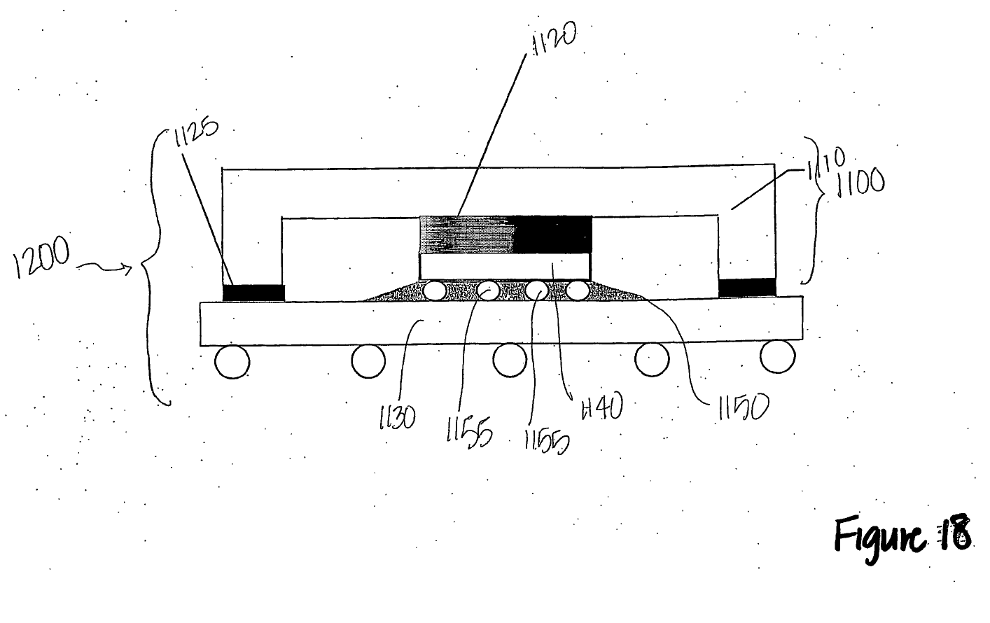

FIGS. 17-18 show another contemplated embodiment of a thermal transfer material 1100 and how it is used in an IC package 1200. FIG. 17 shows a thermal transfer material 1100 which comprises a heat spreader component 1110 and a thermal interface component 1120, which may comprise a phase change material, a tape, a gel or any other suitable thermal interface material. This embodiment also comprises an adhesive component 1125, which in this case may be a high temperature adhesive tape or structural tape, but the adhesive component is not part of the heat spreader component/thermal interface component couple 1100. In FIG. 18, the thermal transfer material 1100 is coupled to a die 1140, an underfill material 1150, which comprises solder material 1155, and a substrate 1130. The adhesive component 1125 in this embodiment is located on the substrate 1130.

Thus, specific embodiments and applications of thermal solutions, IC packaging, thermal interconnect and interface materials have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A thermal transfer material, comprising:
a heat spreader component, wherein the heat spreader component comprises a top surface, a bottom surface and at least one heat spreader material, and
at least one thermal interface material, wherein the thermal interface material is directly deposited onto at least part of the bottom surface of the heat spreader component.

2. The thermal transfer material of claim 1, wherein the thermal material is further coupled to a substrate.

3. The thermal transfer material of claim 2, wherein the substrate comprises silicon.

4. The thermal transfer material of claim 1, wherein the thermal transfer material further comprises at least one adhesive component.

5. The thermal transfer material of claim 4, wherein the at least one adhesive component is coupled to the heat spreader component.

6. The thermal transfer material of claim 4, wherein the at least one adhesive component is coupled to the thermal interface material.

7. The thermal transfer material of claim 4, wherein the at least one adhesive component is mixed into at least some of the thermal interface material.

8. The thermal transfer material of claim 1, wherein the heat spreader component comprises a metal, a metal-based material, a high-conductivity non-metal or combination thereof.

9. The thermal transfer material of claim 8, wherein the heat spreader component comprises nickel, aluminum, copper or a combination thereof.

10. The thermal transfer material of claim 9, wherein the metal-based material or high-conductive non-metal comprises silicon, carbon, copper, graphite, diamond or a combination thereof.

11. The thermal transfer material of claim 10, wherein the heat spreader component comprises a thickness of about 0.25 mm to about 6 mm.

12. The thermal transfer material of claim 11, wherein the thickness is from about 0.5 mm to about 5 mm.

13. The thermal transfer material of claim 1, wherein the thermal interface material comprises a crosslinkable thermal interface material.

14. The thermal transfer material of claim 1, wherein the thermal interface material comprises a phase change material.

15. The thermal transfer material of claim 1, wherein the thermal interface material comprises a polymer solder material, a polymer solder hybrid material or a combination thereof.

16. The thermal transfer material of claim 1, wherein the thermal interface material comprises a conductive filler, a metallic material, a solder alloy and combinations thereof.

17. A method of forming a thermal transfer material, comprising:
providing a heat spreader component, wherein the heat spreader component comprises a top surface, a bottom surface and at least one heat spreader material;
providing at least one thermal interface material, wherein the thermal interface material is directly deposited onto the bottom surface of the heat spreader component; and
depositing the at least one thermal interface material onto the bottom surface of the heat spreader component.

18. The method of claim 17, wherein the thermal transfer material further comprises at least one adhesive component.

19. The method of claim 18, wherein the at least one adhesive component is coupled to the heat spreader component.

20. The method of claim 18, wherein the at least one adhesive component is coupled to the thermal interface material.

21. The method of claim 18, wherein the at least one adhesive component is mixed into at least of the thermal interface material.

22. The method of claim 17, wherein the heat spreader component comprises a metal, a metal-based material, a high-conductivity non-metal or a combination thereof.

23. The method of claim 22, wherein the heat spreader component comprises nickel, aluminum, copper or a combination thereof.

24. The method of claim 22, wherein the metal-based material or high-conductive non-metal comprises silicon, carbon, copper, graphite, diamond or a combination thereof.

25. The method of claim 17, wherein the heat spreader component comprises a thickness of about 0.25 mm to about 6 mm.

26. The method of claim 25, wherein the thickness is from about 0.5 mm to about 5 mm.

27. The method of claim 17, wherein the thermal interface material comprises a crosslinkable thermal interface material.

28. The method of claim 17, wherein the thermal interface material comprises a phase change material.

29. The method of claim 17, wherein the thermal interface material comprises a polymer solder material.

30. The method of claim 17, comprises a conductive filler, a metallic material, a solder alloy and combinations thereof.

31. A method for forming an IC package, comprising:
providing a thermal transfer material;
providing at least one adhesive component;
providing at least one surface or substrate;
coupling the at least one thermal transfer material with the at least one adhesive component to form an adhesive unit; and
coupling the adhesive unit to the at least one surface or substrate to form a thermal package.

32. The method of claim 31, further comprising coupling an additional layer or component to the thermal package.

33. The method of claim 31, wherein the thermal transfer material comprises the thermal transfer material of claim 1.
